(19) United States
(12) Patent Application Publication
(10) Pub. No.: US 2015/0034943 A1
(43) Pub. Date: Feb. 5, 2015

(54) Thin film transistor array substrate

(71) Applicant: HannStar Display Corp., New Taipei City (TW)

(72) Inventors: Chia-Hua Yu, New Taipei City (TW); Hsien-Tang Hu, Taichung City (TW); Ko-Ruey Jen, Taipei City (TW); Jui-Chi Lai, Kaohsiung City (TW)

(73) Assignee: HannStar Display Corp., New Taipei City (TW)

(21) Appl. No.: 14/222,669

(22) Filed: Mar. 23, 2014

(30) Foreign Application Priority Data
Aug. 5, 2013 (CN) 201310336532.8

(51) Int. Cl. H01L 29/786

(52) U.S. Cl. CPC H01L 29/78693
USPC 257/43

(57) ABSTRACT

The present invention discloses a thin film transistor array substrate comprising a plurality of thin film transistors, with each one thereof including a gate electrode, a gate insulation layer, an amorphous-oxide semiconductor layer and a pair of a source electrode and a drain electrode. The amorphous-oxide semiconductor layer comprises an amorphous-oxide semiconductor material having a-IGZO. The thin film transistor array substrate further comprises a first insulation layer and a second insulation layer disposed on the thin film transistors. Since the a-IGZO semiconductor layer and the thick insulation layer covered thereon are used in the present invention, a common electrode can overlap the scan lines or data lines to increase the aperture ratio of the pixel structure. Furthermore, the thick insulation layer can be fabricated through a coating process, so as to keep the a-IGZO semiconductor layer from damages during the fabrication processes.

### BACKGROUND OF THE INVENTION

1. Field of the Invention

The present invention relates to a display panel, and more particularly, a thin film transistor (TFT) array substrate.

2. Description of the Prior Art

A thin-film transistor (TFT), which serves as an active device for driving each pixel structure of a display panel, has been widely applied in active matrix flat display panels, such as active liquid crystal display panels or active organic electroluminescent display panels. The conventional thin-film transistor structure is based on a bottom gate structure. The bottom gate structure includes a gate electrode disposed on a substrate, a gate insulation layer covering the gate electrode, a semiconductor layer serving as a transistor channel, and a pair of a source electrode and a drain electrode disposed at two sides of the semiconductor layer respectively. The thin-film transistor is mainly divided to the inverted co-planar type, back channel etching (BCE) type and channel protection (CHP) type. The semiconductor layer can comprise IGZO material which stands for indium gallium zinc oxide. In other words, the a-IGZO material is an amorphous-oxide semiconductor material having indium oxide, gallium oxide, and zinc oxide. As shown in FIG. 1, a back channel etching type thin film transistor array substrate 2 comprises a substrate 4, a gate electrode 6, a gate insulation layer 8, an a-IGZO semiconductor layer 10 disposed on the gate insulation layer 8, a pair of a source electrode 12 and a drain electrode 14 disposed on two sides of the gate insulation layer 8 and the a-IGZO semiconductor layer 10 over the gate electrode 6 respectively and covered with a passivation layer 16, and a pixel electrode 18 formed on the passivation layer 16 and contacted the drain electrode 14 through a contact hole 20. However, in order to avoid capacitive coupling, the pixel electrode 18 usually do not overlap any scan line (also known as gate line), data line (also known as signal line), or thin film transistor, thus that the aperture ratio of the pixel electrode will be limited accordingly.

Furthermore, in the fabrication of the thin film transistor comprising the a-IGZO semiconductor layer, a hydrogenous processing has to be avoided. For example, the IGZO layer is disposed on the gate insulation layer which usually comprises a SiO film having a low amount of hydrogen and is formed by chemical vapor deposition (CVD). However, silane (SiH₄) used in the CVD comprises a great amount of hydrogen which may reduce the a-IGZO and result in defects. Generally, a common performance will adjust a SiH₄/N₂O ratio from 1:5 to between 1:50 and 1:100, and carry out a low-temperature film-forming process at around 200° C., preferably forming the SiO₂ film or the Al₂O₃ film through a physical vapor deposition (PVD) process, or other film-forming processes which will not lead to the reduction of the a-IGZO.

After forming the IGZO semiconductor layer, the insulation layer is fabricated, and the insulation layer has stricter requirement about hydrogen content and must be formed under lower amount of hydrogen, in comparison with the fabrication of the gate insulation layer. Hence, a SiH₄/N₂O ratio between 1:50 and 1:100 and a low-temperature film-forming process at around 200° C. must be required. Preferably, the SiO₂ film or the Al₂O₃ film is formed through a PVD process or other film-forming processes which will not lead to the reduction of the a-IGZO.

However, the aperture ratio of the pixel electrode of the liquid crystal display panel consisted of such thin film transistor array substrate is still limited. Accordingly, significantly increasing the aperture ratio of the pixel electrode and no interfering the a-IGZO semiconductor layer during the fabrication process is a main objective in the field.

### SUMMARY OF THE INVENTION

It is one of the objectives of the present invention to provide a thin film transistor array substrate which utilizes an a-IGZO semiconductor layer and an insulation layer covered thereon to increase the aperture ratio of the pixel structure, and also to keep the a-IGZO semiconductor layer from possible defects during the fabrication process.

To achieve the purposes described above, a thin film transistor array substrate in accordance with a preferred embodiment of the present invention is disclosed and comprises a transparent substrate, a plurality of thin film transistors, a first insulation layer, a common electrode, a second insulation layer, and a plurality of pixel electrodes. The thin film transistors are disposed on the transparent substrate. Each of the thin film transistors comprises a gate electrode disposed on the transparent substrate, a gate insulation layer disposed on the gate electrode and covering the transparent substrate, an oxide semiconductor layer disposed on the gate insulation layer on the gate electrode, and a pair of a source electrode and a drain electrode disposed on two sides of the oxide semiconductor layer respectively, wherein a portion of the source electrode and a portion of the drain electrode overlap the oxide semiconductor layer. The oxide semiconductor layer comprises an amorphous-oxide semiconductor material having indium oxide, gallium oxide and zinc oxide, also named as IGZO material. The first insulation layer is disposed on the thin film transistors and the transparent substrate. The thin film transistor array substrate further comprises a plurality of contact holes penetrating through the first insulation layer and exposing one of the pair of the source electrode and the drain electrode corresponding thereto. The common electrode is disposed on the first insulation layer and the contact holes are exposed by the common electrode. The second insulation layer covers the common electrode. Each of the pixel electrodes is disposed on the second insulation layer and fills in each of the contact holes respectively, thereby contacting the one of the pair of the source electrode and the drain electrode exposed from each of the contact holes.

According to another preferred embodiment of the present invention, a thin film transistor array substrate based on the aforementioned preferred embodiment is disclosed and comprises a plurality of thin film transistors disposed on the transparent substrate within a display region. The thin film transistor further comprises a plurality of direct contact structures disposed respectively on the transparent substrate within a fanout region. Each of the direct contact structures comprises a first contact layer, a first contact hole, and a second contact layer all disposed on the transparent substrate, and the gate insulation layer covers the first contact layer. The first contact hole penetrates through the gate insulation layer and exposes the first contact layer. The second contact layer is disposed on the gate insulation layer and fills in the first contact hole, thereby contacting the first contact layer. The first insulation layer is also disposed on the direct contact structures.

According to another preferred embodiment of the present invention, a thin film transistor array substrate based on aforementioned preferred embodiment is disclosed and further comprises a plurality of scan lines electrically connected to the gate electrodes in each of the thin film transistors, and a plurality of data lines electrically connected to a first end of one of the pair of the source electrode and the drain electrode in each of the thin film transistors. The first insulation layer is also disposed on the scan lines and the data lines.

In the thin film transistor array substrate of the present invention, since the oxide semiconductor layer comprises an amorphous-oxide semiconductor material, such as indium oxide, gallium oxide, and zinc oxide, which is beneficial in miniaturization, high precision and low power consumption. Also, the first insulation layer is fabricated through a coating process which will not lead to the reduction of the oxide semiconductor layer, so that the oxide semiconductor layer can achieve preferable electric property. Further, the first insulation layer is thick enough to avoid unnecessary capacitive coupling, so as to increase the aperture ratio of the pixel electrodes. Hence, the thin film transistor array substrate in accordance with the present invention is sufficient to obtain preferable electric property.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a cross-sectional view of a conventional thin film transistor array substrate.

FIG. 2 illustrates a bottom view of a thin film transistor array substrate in accordance with an embodiment of the present invention.

FIG. 3 to FIG. 5 are cross sectional views along the cross line A-A′ of a thin film transistor array substrate in accordance with a first preferred embodiment shown in FIG. 2 and illustrate the fabrication process of the thin film transistor array substrate.

FIG. 6 to FIG. 7 are cross sectional views along the cross line A-A′ of a thin film transistor array substrate in accordance with a second preferred embodiment shown in FIG. 2 and illustrate the fabrication process of the thin film transistor array substrate.

FIG. 8 and FIG. 9 are cross sectional views along the cross line A-A′ of a thin film transistor array substrate in accordance with a third preferred embodiment shown in FIG. 2 and illustrate the fabrication process of the thin film transistor array substrate.

FIG. 10 and FIG. 11 are cross sectional views along the cross line A-A′ and B-B′ of a thin film transistor array substrate in accordance with a fourth preferred embodiment shown in FIG. 2 and illustrate the fabrication process of the thin film transistor array substrate.

FIG. 12 and FIG. 13 are cross sectional views along the cross line A-A′ and B-B′ of a thin film transistor array substrate in accordance with a fifth preferred embodiment shown in FIG. 2 and illustrate the fabrication process of the thin film transistor array substrate.

FIG. 14 and FIG. 15 are cross sectional views along the cross line A-A′ and B-B′ of a thin film transistor array substrate in accordance with a sixth preferred embodiment shown in FIG. 2 and illustrate the fabrication process of the thin film transistor array substrate.

FIG. 16 is a cross sectional view illustrating a thin film transistor array substrate in accordance with an embodiment of the present invention and illustrating the thin film transistor array substrate being applied to a liquid crystal display panel.

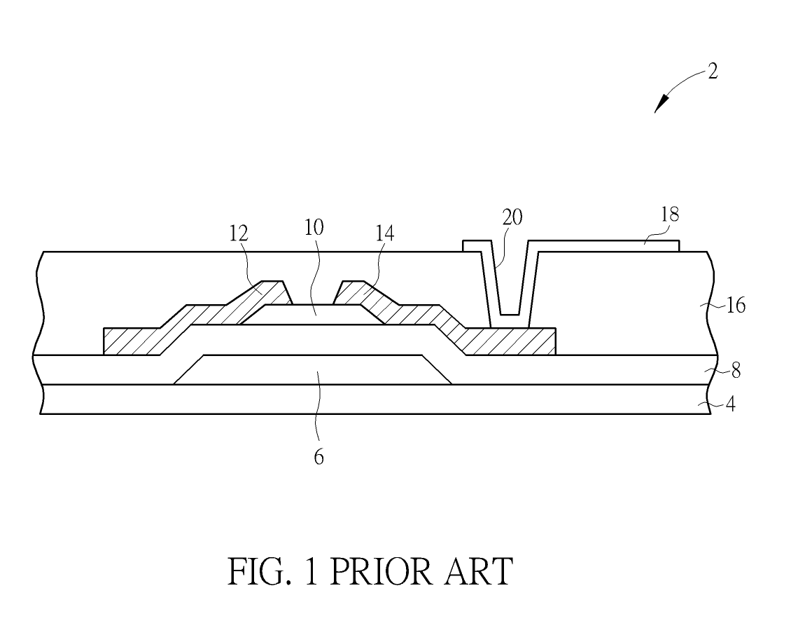

### DETAILED DESCRIPTION

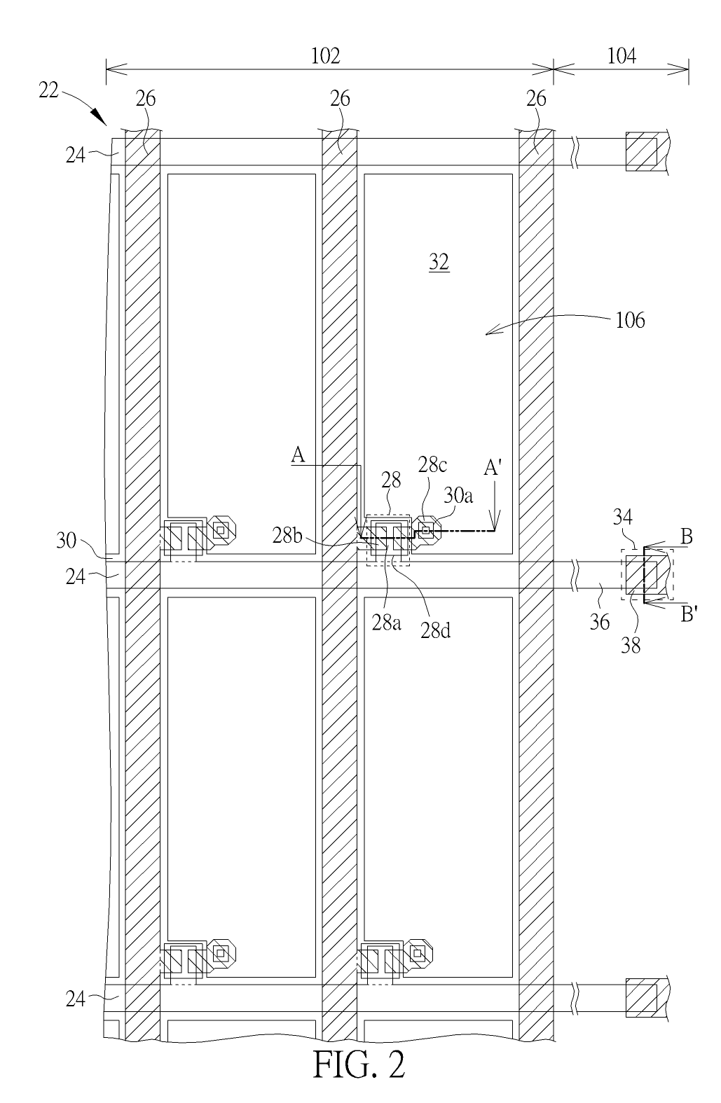

FIG. 2 is a bottom view of a thin film transistor array substrate in accordance with an embodiment of the present invention. The thin film transistor array substrate 22 comprises a display region 102 and a fanout region 104, and further comprises a plurality of scan lines 24, a plurality of data lines 26, a plurality of thin film transistors 28, a common electrode 30 and a plurality of pixel electrodes 32 within the display region 102. The data lines 26 intersect the scan lines 24, and any two adjacent data lines 26 and any two adjacent scan lines 24 define a pixel region 106, so that the pixel regions 106 are arranged in a matrix. Each of the thin film transistors 28 is disposed within each of the pixel regions 106, and each of the thin film transistors 28 comprises a gate electrode 28a, a source electrode 28b, and a drain electrode 28c, and also comprises agate insulation layer (not shown in the drawing) and a semiconductor layer 28d. Furthermore, the gate electrode 28a is electrically connected to a corresponding scan line 24, and the drain electrode 28b is electrically connected to a corresponding data line 26. In this embodiment of the present invention, the semiconductor layer 28d is used as a channel.

In addition, the common electrode 30 can overlap the thin film transistors 28, the data lines 26 and the scan lines 24, for shielding the capacitive coupling between any one of the thin film transistors 28, the data lines 26 and the scan lines 24 and an electrode or a wire disposed on the common electrode 30. With such arrangement, it can reduce the gaps between the thin film transistors 28, the data lines 26 or the scan lines 24 and the electrode or the wire disposed on the common electrode 30 in a direction parallel to a first substrate. In other embodiments of the present invention, the common electrode can optionally overlap one or two of the thin film transistors, the data lines and the scan lines. Also, each of the pixel electrodes 32 is disposed within each of the pixel regions 106 and is electrically connected to the drain electrode 28c in each of the thin film transistors 28.

The fanout region 104 is defined in a periphery circuit zone of the thin film transistor array substrate 22. The periphery circuit zone generally comprises a driving circuit and the fanout region 104. The thin film transistor array substrate 22 in the fanout region 104 comprises a plurality of wires extending from the display region 102 to the periphery circuit zone. The thin film transistor array substrate 22 of the present invention can comprise a direct contact structure 34 within the fanout region 104. The direct contact structure 34 is regarded as a connecting point of signaling circuits. For example, a wire 36 fabricated from a first conductive layer is directly connected to a wire 38 fabricated from a second conductive layer, so as to join up the transmitted signals in series.

For detail describing the thin film transistor array substrate of the present embodiment, the structure of a single pixel region 106 is illustrated in following paragraphs, and however, the present invention is not limited thereto.

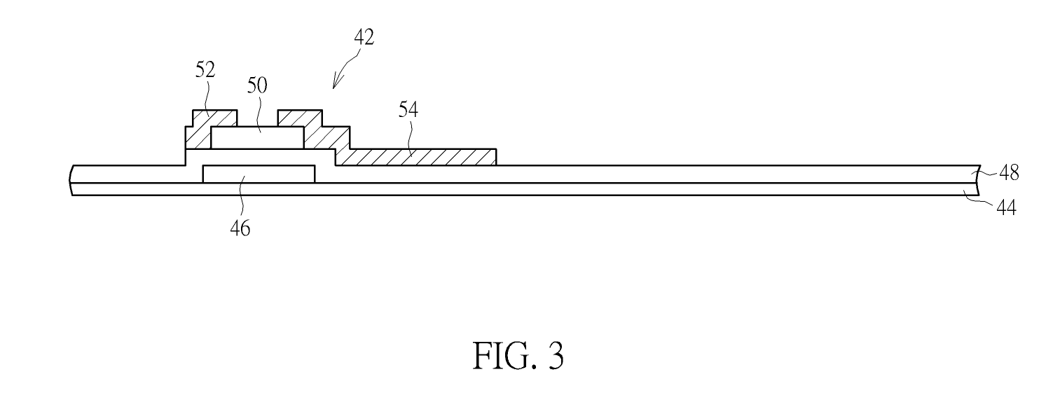

Referring FIG. 2 and FIG. 3 to FIG. 5, a thin film transistor array substrate, as well as a fabrication method thereof, in accordance with a first preferred embodiment in the present invention are illustrated, wherein, FIG. 2 provides a layout of the elements shown in the cross sectional views of FIG. 3 to FIG. 5. As shown in FIG. 3, a transparent substrate 44 is first provided. The transparent substrate 44 may comprise a glass or a suitable plastic material. A conductive material layer is then fabricated on the transparent substrate 44 through a sputtering process, and a first photolithography process is carried out to etch the conductive material layer on the transparent substrate 44 to form a first conductive layer. The first conductive layer can comprise a scan line (not shown in the drawings), and a gate electrode 46. The first conductive layer can comprise a material of Mo/Al/MO, Al/Mo, Mo, MoW, Cu, Cu/Mo, or Ti/Al/Ti but not limited thereto. Then, a gate insulation layer 48 is fabricated on the first conductive layer and the transparent substrate 44 through a CVD process. The gate insulation layer 48 may comprise a dielectric material, such as a film having silicon oxide, silicon nitride, or aluminum oxide. Next, an oxide semiconductor material layer is fabricated on the gate insulation layer 48, and a second photolithography process is carried out to etch the oxide semiconductor material layer on the gate insulation layer 48 to form an oxide semiconductor layer 50, also named as an active layer. The oxide semiconductor layer 50 can comprise an amorphous-oxide semiconductor material having indium, gallium, and zinc, which is also known as a-IGZO material. The a-IGZO material can be fabricated through aforementioned conventional methods.

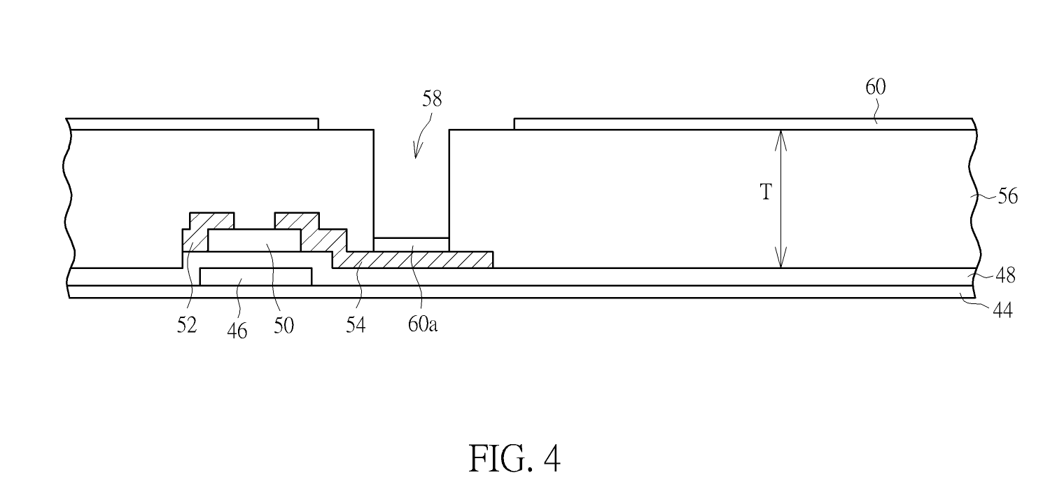

Turning next, another conductive material layer is fabricated on the gate insulation layer 48 and the oxide semiconductor layer 50 through a sputtering process, and then a third photolithography process is carried out to etch the conductive material layer on the gate insulation layer 48 and the oxide semiconductor layer 50 to form a second conductive layer. The second conductive layer comprises a source electrode 52, a drain electrode 54 and a data line (not shown in the drawing) probably disposed on other portions of the transparent substrate 44. The second conductive layer can comprise a material of Mo/Al/MO, Al/Mo, Mo, MoW, Cu, Cu/Mo, or Ti/Al/Ti. Preferably, the selective ratio of etching the second conductive layer relative to etching the a-IGZO semiconductor material is more than 3:1 either for the wet etching or the dry etching used in the third photolithography process. Thus, the thin film transistor 42 of this embodiment is consisted of the source electrode 52, the drain electrode 54, the oxide semiconductor layer 50 and the scan line partially overlapped the oxide semiconductor layer 50 (regarding as the gate electrode 46). The drain electrode 54 has a portion extending onto the gate insulation layer 48 on the transparent substrate 44. After that, as shown in FIG. 4, a first insulation layer 56, being an overcoat layer (OC), is fabricated on the second conductive layer and the gate insulation layer 48 through a coating process. Accordingly, the first insulation layer 56 can be formed on the thin film transistor 42, the scan line, the data line and the transparent substrate 44, and covers them. The first insulation layer 56 comprises a transparent inorganic material or an organic material which will not react with the a-IGZO and lead to the reduction and oxidation of the a-IGZO, such as polysiloxane, silicon oxides, or acrylic. Wherein, the polysiloxane comprise a composition selected from a group of Si, O, C and H; the silicon oxide comprise a composition selected from a group of Si and O; and the acrylic comprise a composition selected from a group of O, C, and H. The first insulation layer 56 has a thickness T, for example being between 1 μm and 5 μm. Also, the first insulation layer 56 is fabricated through the coating process which is performed at a low temperature, thus the a-IGZO semiconductor layer is less easy to be oxidized or reduced. During the coating process, a suitable solvent and a suitable dry and solidified method are needed according to real requirements. Then as shown in FIG. 4, a fourth photolithography process is carried out to form a plurality of contact holes 58 on the first insulation layer 56, wherein each of the contact holes 58 is disposed corresponding to the drain electrode 54. In other words, the drain electrode 54 is exposed from the contact holes 58. Further, the first insulation layer 56 can comprise a photoresist layer, and the contact holes 58 can be fabricated through a conventional process by patterning the photoresist layer.

Please note that when referring to the words “on” or “above” that describe the relationship between components in the text, it is well known in the art and should be clearly understood that these words refer to a direct or indirect contact positions between components.

In the first preferred embodiment, the thin film transistor 42 is a back channel etch type thin film transistor.

Then, a transparent conductive layer is fabricated on the first insulation layer 56, and a fifth photolithography process is carried out to etch the transparent conductive layer to form a common electrode 60. The common electrode 60 can comprise a proper conductive material, such as ITO, IZO, or carbon nanotube. The common electrode 60 comprises an opening greater than the contact hole 58, so as to expose the entire contact hole 58 and a portion of the first insulation layer 56 surrounding the contact hole 58. During the fabrication, the transparent conductive layer can also be formed on a side wall, a bottom or both of the side wall and the bottom of the contact hole 58, wherein the bottom of the contact hole is just corresponding to the exposed drain electrode 54. The transparent conductive layer disposed on the side wall, the bottom or both of the side wall and the bottom of the contact hole 58 can be optionally removed before the fabrication of the common electrode 60. If the transparent conductive layer disposed on the side wall, the bottom or both of the side wall and the bottom of the contact hole 58 is remained, then enough distance is required between the common electrode 60 and the remained transparent conductive layer to insulate from each other in the following processes. This embodiment shown in FIG. 4 illustrates a portion of the transparent conductive layer 60a formed on the drain electrode 54.

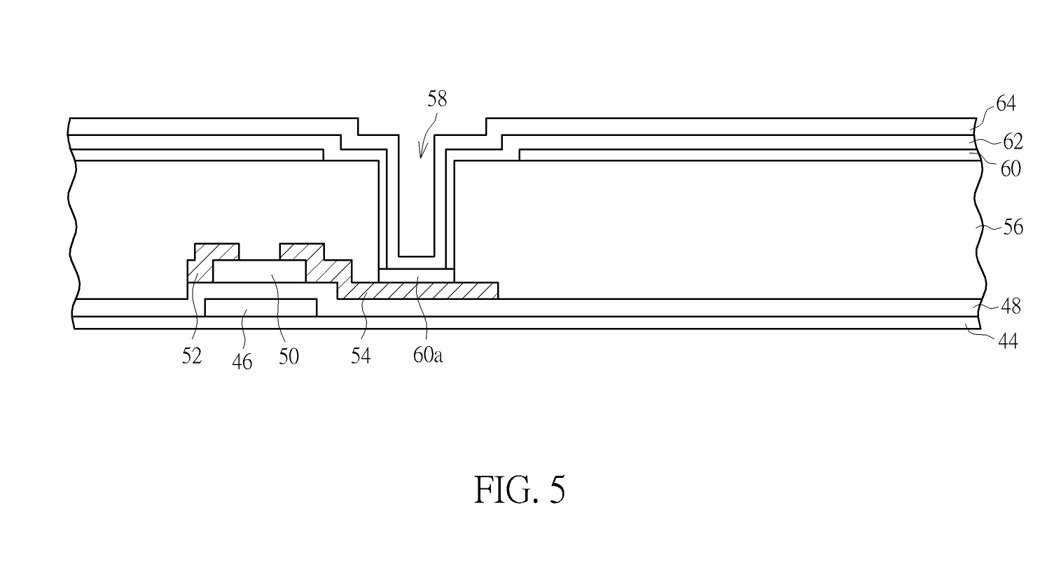

As following, an insulation layer is fabricated on the common electrode 60 and the first insulation layer 56. As shown in FIG. 5, a sixth photolithography process is carried out to etch the insulation layer to form a second insulation layer 62 having an opening for exposing the bottom of the contact hole 58. The second insulation layer 62 is namely a passivation layer in the prior art. The second insulation layer 62 can comprise a film of silicon oxide, silicon nitride, or aluminum oxide, and may be fabricated through a CVD process.

Finally, another transparent conductive layer is fabricated on the second insulation layer 62, and filled in the contact hole 58. Then, a seventh photolithography process is carried out to etch the transparent conductive layer to form a pixel electrode 64. The pixel electrode 64 is further filled in the contact hole 58, thereby being electrically contacted to the drain electrode 54. With such arrangement, the thin film transistor array substrate of this embodiment is fabricated. The pixel electrode 64 can comprise ITO, IZO or carbon nanotube.

The first insulation layer 56 has a thickness which is greater than a thickness of the second insulation layer 62, but the present invention is not limited thereto. The thickness of the first insulation layer 56 can be 1 to 5 μm. The thickness of the second insulation layer 62 can be 0.3 to 5 μm for example. The first insulation layer 56 is thick enough to avoid capacitive coupling between the common electrode 60 and anyone of the thin film transistor, the data line and the scan line, and accordingly the area of the pixel electrode 64 can further extend to overlap the scan line or the data line. In this embodiment, the common electrode 60 between the scan line and the pixel electrode 64 and between the data line and the pixel electrode 64 can be utilized to provide shielding and to prevent from the interferences between the pixel electrode 64 and the scan line and between the pixel electrode 64 and the data line. In other words, in the present invention, the pixel electrode can overlap a portion of at least one of the scan line and the data line, with the first insulation layer and the common electrode being sandwiched between the pixel electrode and the portion of at least one of the scan line and the data line.

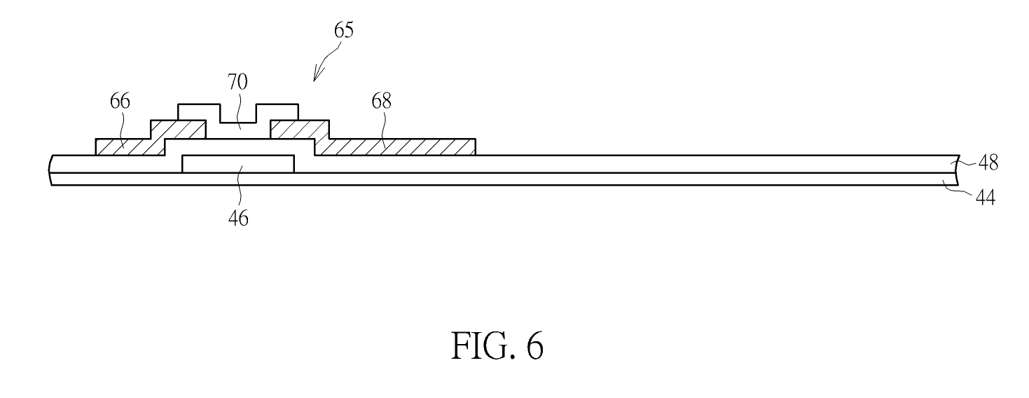

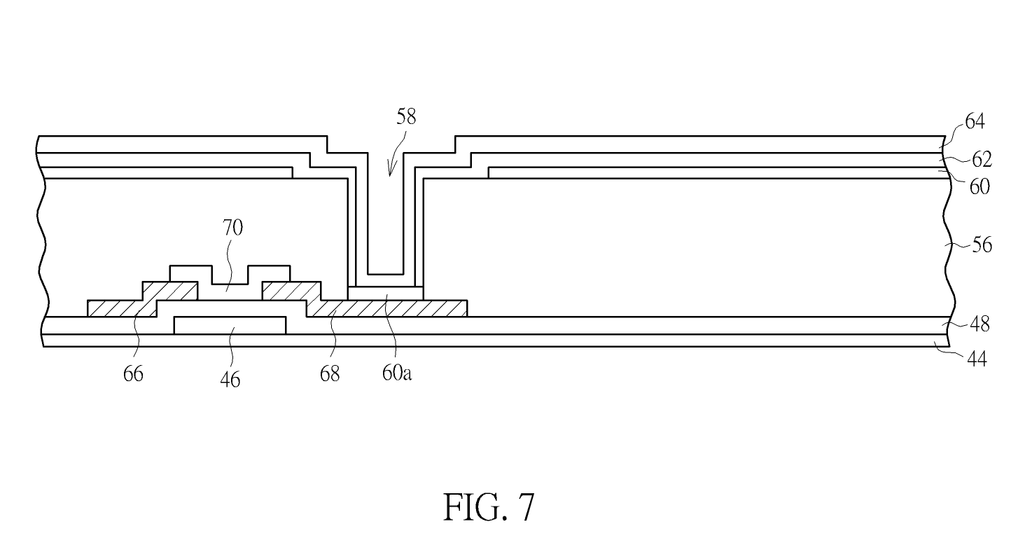

The present invention may have other variant embodiments. A thin film transistor array substrate in accordance with the second preferred embodiment, as well as the fabrication thereof, is illustrated in FIG. 2, FIG. 6 and FIG. 7. FIG. 2 provides a layout of the elements shown in the cross sectional views of FIG. 6 and FIG. 7. The difference between this embodiment and the first preferred embodiment is characterized in the structure and the fabrication processes of the thin film transistor 65. As shown in FIG. 6, a first conductive layer is formed on the transparent substrate 44 through a first photolithography process, and the first conductive layer comprises a scan line (do not shown in the drawing) and a gate electrode. Then, the gate insulation layer 48 is fabricated, and a second conductive layer is fabricated on the gate insulation layer 48 through a second photolithography process. The second conductive layer comprises a pair of a source electrode 66 and a drain electrode 68, and a data line (not shown in the drawings), and a portion of the gate insulation layer 48 is exposed from a gap between the source electrode 66 and the drain electrode 68. The drain electrode 68 can comprise a portion which extends onto the gate insulation layer 48 on the transparent substrate 44. As following, an oxide semiconductor material layer is fabricated on the source electrode 66, the drain electrode 68, and the portion of the gate insulation layer 48 exposed from the gap between the source electrode 66 and the drain electrode 68, and a third photolithography process is carried out to etch the oxide semiconductor material layer on the source electrode 66, the drain electrode 68 and the portion of the gate insulation layer 48 exposed from the gap between the source electrode 66 and the drain electrode 68 to form an oxide semiconductor layer 70. The oxide semiconductor layer 70 can comprise an amorphous-oxide semiconductor material having indium, gallium, and zinc, which is also known as a-IGZO material. The a-IGZO material can be fabricated through wet etching, and preferably the wet etching is performed under an etching selectivity of more than 3 (a-IGZO relative to the second conductive layer). Thus, the thin film transistor 65 of this embodiment is consisted of the source electrode 66, the drain electrode 68, the oxide semiconductor layer 70, and the gate electrode 46.

In the second preferred embodiment, the thin film transistor 65 is an inverted co-planar type thin film transistor. The oxide semiconductor layer 70 is disposed between the first insulation layer 56, and the pair of the source electrode 66 and the drain electrode 68, thereby contacting to the gate insulation layer 48 through the gap between the source electrode 66 and the drain electrode 68.

Then, as shown in FIG. 7, similar to the first preferred embodiment, the first insulation layer 56 is fabricated, as following, the contact hole 58 is fabricated through a fourth photolithography process; the common electrode 60 is fabricated through a fifth photolithography process; the second insulation layer 62 is fabricated through a sixth photolithography process; and the pixel electrode 64 is fabricated through a seventh photolithography process.

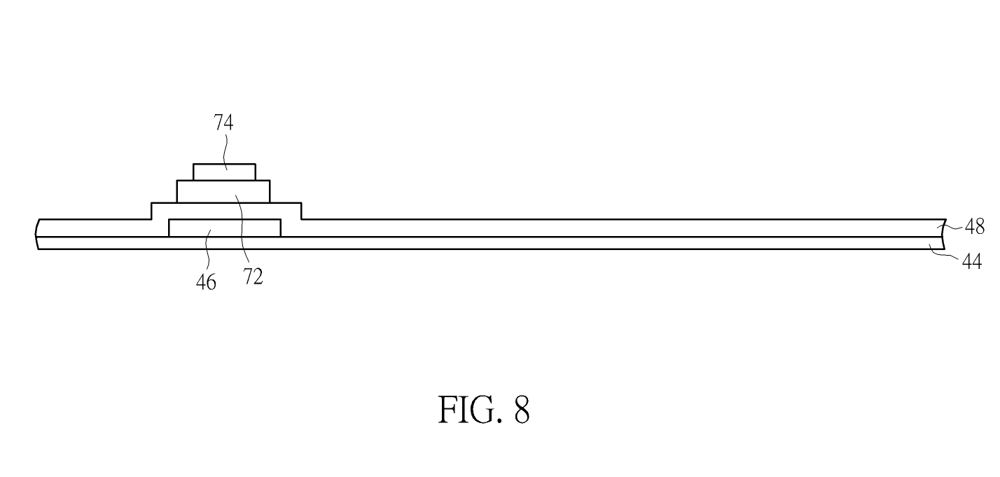

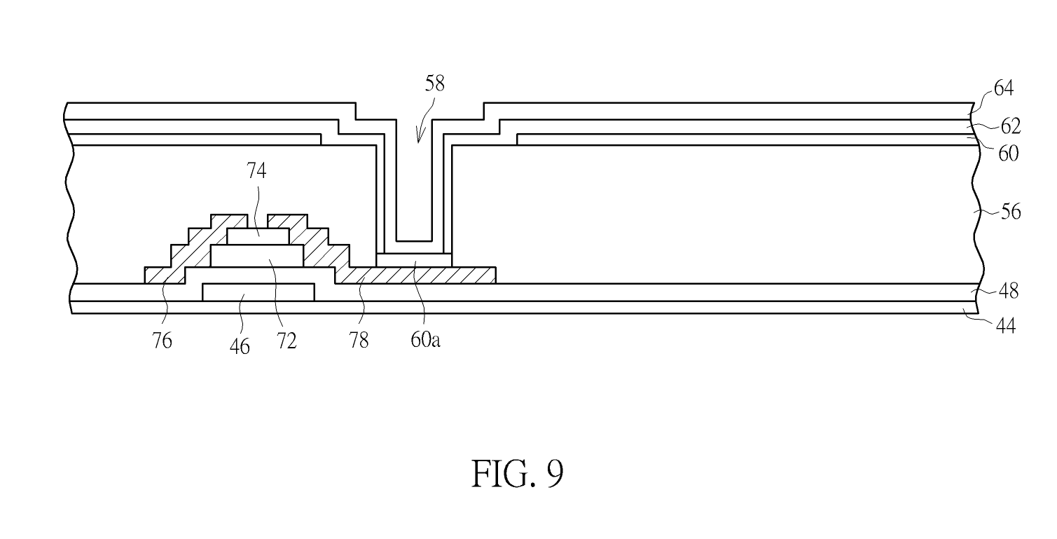

A thin film transistor array substrate in accordance with the third preferred embodiment and the fabrication the same is illustrated in FIG. 2, FIG. 8 and FIG. 9. FIG. 2 provides a layout of each element shown in the cross sectional views of FIG. 8 and FIG. 9. The difference between the present embodiment and the first preferred embodiment is characterized in the structure and the fabrication processes of the thin film transistor. As shown in FIG. 8, a first conductive layer is fabricated on the transparent substrate 44 through a first photolithography process, and the first conductive layer may comprise a plurality of scan line (do not shown in the drawing) and a gate electrode. Then, the gate insulation layer 48 is fabricated, and an oxide semiconductor layer 72 is fabricated on the gate insulation layer 48 through a second photolithography process. The oxide semiconductor layer 72 can comprise an a-IGZO material. After that, an etching stop layer 74 is fabricated on the oxide semiconductor layer 72 through a third photolithography process. The etching stop layer 74 may comprise a film of SiO, SiN, or Al₂O₃, and which is used for shielding the channel of semiconductor layer generated by the oxide semiconductor layer 72.

Then, as shown in FIG. 9, a second conductive layer is fabricated on the gate insulation layer 48, the oxide semiconductor layer 72 and the etching stop layer 74 through a fourth photolithography process. The second conductive layer comprises a pair of a source electrode 76 and a drain electrode 78, and a data line disposed at other portions of the transparent substrate 44 (not shown in the drawings). Thus, the thin film transistor of the present embodiment is consisted of the source electrode 76, the drain electrode 78, the oxide semiconductor layer 72, and the gate electrode 46. In the second preferred embodiment, the thin film transistor 42 is a channel protection type thin film transistor, the oxide semiconductor layer 72 is disposed between the gate insulation layer 48 and the pair of the source electrode 76 and the drain electrode 78, and the thin film transistor further comprises the etching stop layer 74 disposed on the oxide semiconductor layer 72, between the pair of the source electrode 76 and the drain electrode 78.

Then, similar to the first preferred embodiment, the first insulation layer 56 is formed, as following, the contact hole 58 is fabricated through a fifth photolithography process; the common electrode 60 is fabricated through a sixth photolithography process; the second insulation layer 62 is fabricated through a seventh photolithography process; and the pixel electrode 64 is fabricated through an eighth photolithography process.

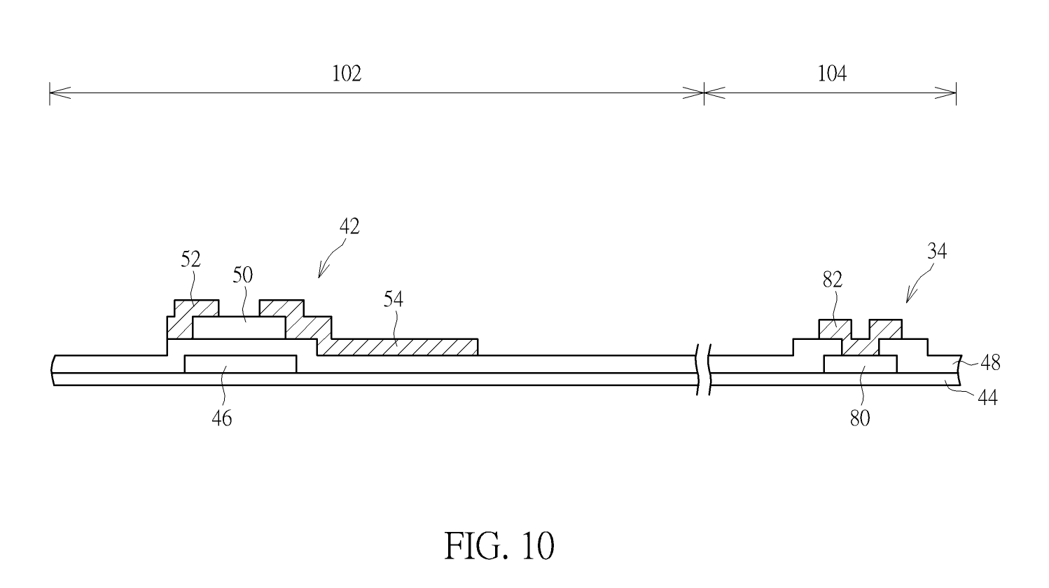

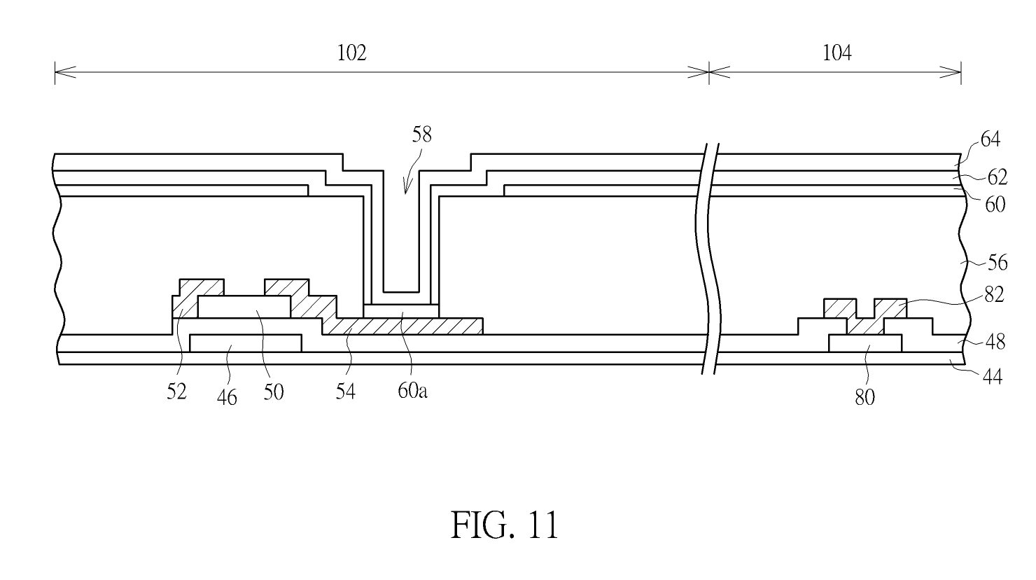

A thin film transistor array substrate in accordance with the fourth preferred embodiment and the fabrication the same is illustrated in FIG. 2, FIG. 10 and FIG. 11. FIG. 2 provides the layout of each element shown in the cross sectional views of FIG. 10 and FIG. 11. The difference between this embodiment and the first preferred embodiment is characterized in forming a direct contact structure 34 within the fanout region 104 at the same time. Since the gate insulation layer 48 of this embodiment need to be patterned to form an opening of the direct contact structure 34, an additional photolithography process is required, in comparison with the first preferred embodiment. As shown in FIG. 10, a first conductive layer is fabricated on the transparent substrate 44 through a first photolithography process, and the first conductive layer may comprise a scan line (do not shown in the drawing) within the display region 102, agate electrode, and one or more than one of first contact layer 80 within the fanout region 104. Thus the first contact layer 80 may comprise the same material to the gate electrode 46. Next, the gate insulation layer 48 is fabricated on the gate electrode 46, as well as the first contact layer 80. A portion of the gate insulation layer 48 disposed above each of the first contact layer 80 is then fabricated to have the contact hole. After that, an oxide semiconductor layer 50 is fabricated on the gate insulation layer 48 through a third photolithography process, and a second conductive layer is fabricated through a fourth photolithography process. The second conductive layer comprises a pair of a source electrode 52 and a drain electrode 54, a data line disposed at other portions of the transparent substrate 44 (not shown in the drawings), and a second contact layer 82 disposed on the first contact layer 80 and filled in the contact hole. Accordingly, the second contact layer 82, the pair of the source electrode 52 and the drain electrode 54 can comprise the same material. Thus, the thin film transistor 42 of the present embodiment is consisted of the source electrode 52, the drain electrode 54, the oxide semiconductor layer 50, and the gate electrode 46, wherein the first contact layer 80 direct contacts to the second contact layer 82 through the contact hole, so as to form the direct contact structure 34.

Then, as shown in FIG. 11, similar to the first preferred embodiment, the first insulation layer 56 is formed to cover the display region 102 and the fanout region 104, as following, the contact hole 58 is fabricated through a fifth photolithography process; the common electrode 60 is fabricated through a sixth photolithography process; the second insulation layer 62 is fabricated through a seventh photolithography process; and the pixel electrode 64 is fabricated through an eighth photolithography process.

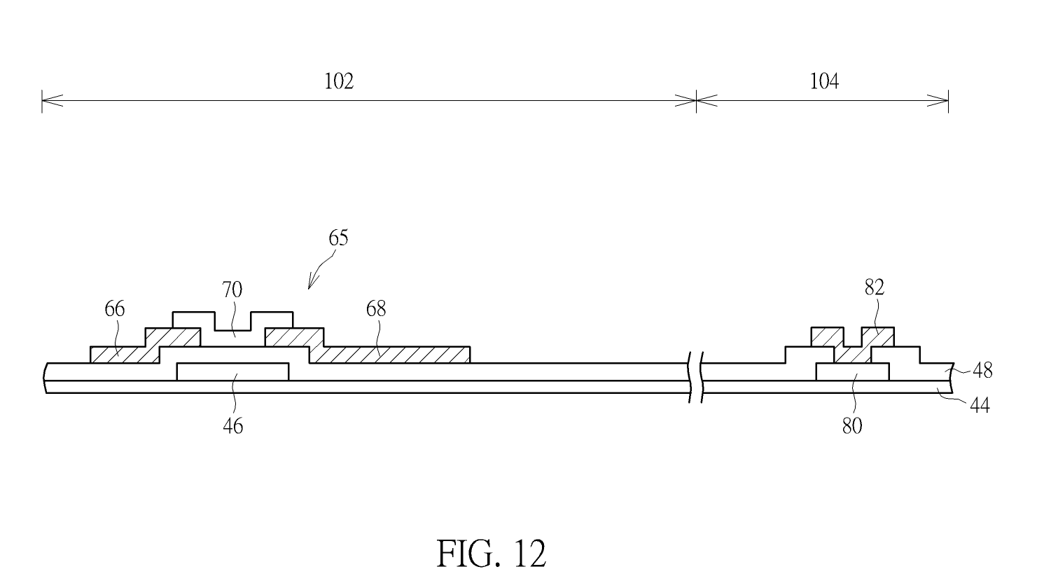

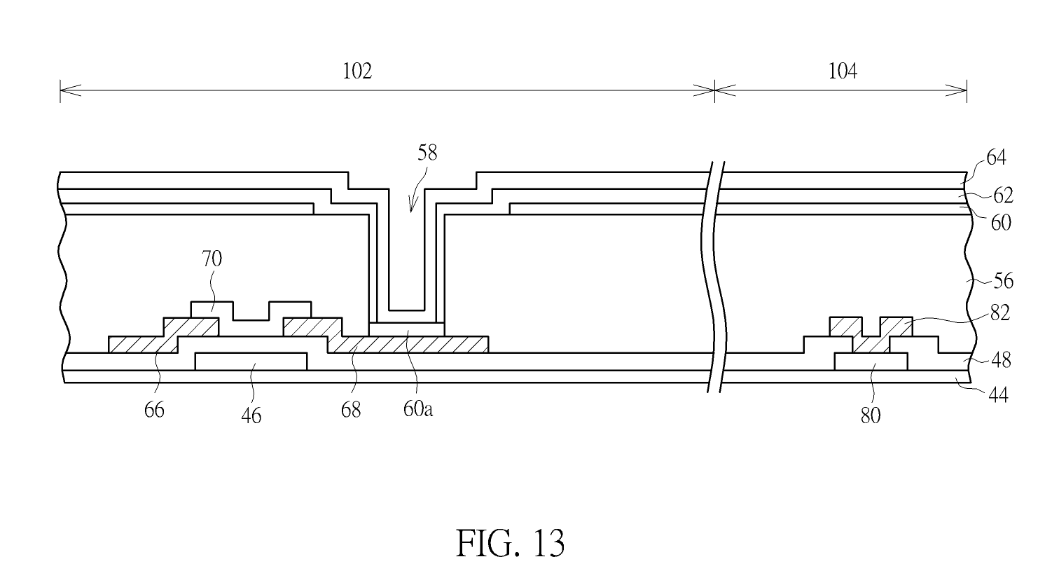

A thin film transistor array substrate in accordance with the fifth preferred embodiment and the fabrication the same is illustrated in FIG. 2, FIG. 12 and FIG. 13. FIG. 2 provides the layout of each element shown in the cross sectional views of FIG. 12 and FIG. 13. The difference between the present embodiment and the first preferred embodiment is characterized in forming the direct contact structure 34 within the fanout region 104 at the same time. Since the gate insulation layer 48 of the present embodiment need to be patterned to form the opening of the direct contact structure 34, an additional photolithography process is required, in comparison with the second preferred embodiment. As shown in FIG. 12, a first conductive layer is fabricated on the transparent substrate 44 through a first photolithography process, and the first conductive layer may comprise a scan line (do not shown in the drawing), within the display region 102, a gate electrode 46, and one or more than one of first contact layer 80, within the fanout region 104. Next, the gate insulation layer 48 is fabricated, wherein the gate insulation layer 48 covers the gate electrode 46, as well as the first contact layer 80. The contact hole is then fabricated on a portion of the gate insulation layer 48 being above each of the first contact layer 80, so as to expose the first contact layer 80 therebelow. After that, a second conductive layer is formed on the gate insulation layer 48 through a third photolithography process. The second conductive layer comprises a plurality of pairs of the source electrode 66 and the drain electrode 68, within the display region 102, and one or more than one of the second contact layer 82, within the fanout region 104, and the first contact layer 80 direct contacts to the second contact layer 82 through the contact hole, so as to form the direct contact structure 34. Then, the oxide semiconductor layer 70 is fabricated on the source electrode 66, the drain electrode 68 and the portion of the gate insulation layer 48 exposed from the gap between the source electrode 66 and the drain electrode 68 through a fourth photolithography process. Thus, the thin film transistor 65 of the present embodiment is consisted of the source electrode 66, the drain electrode 68, the oxide semiconductor layer 70, and the gate electrode 46.

Then, as shown in FIG. 13, similar to the fourth preferred embodiment, the first insulation layer 56 is formed, as following, the contact hole 58 is fabricated through a fifth photolithography process; the common electrode 60 is fabricated through a sixth photolithography process; the second insulation layer 62 is fabricated through a seventh photolithography process; and the pixel electrode 64 is fabricated through an eighth photolithography process.

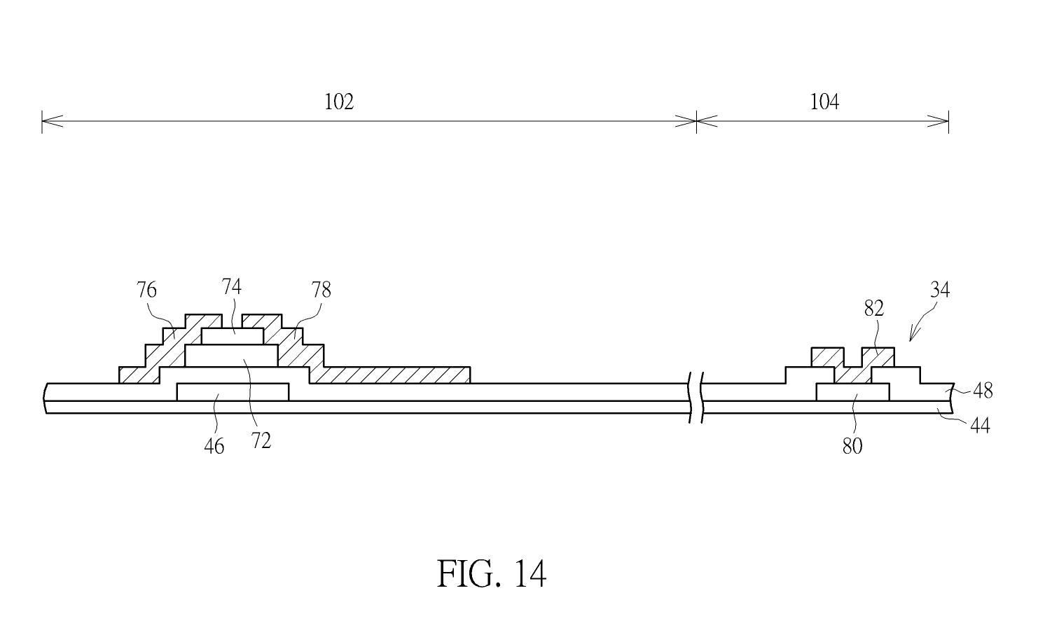

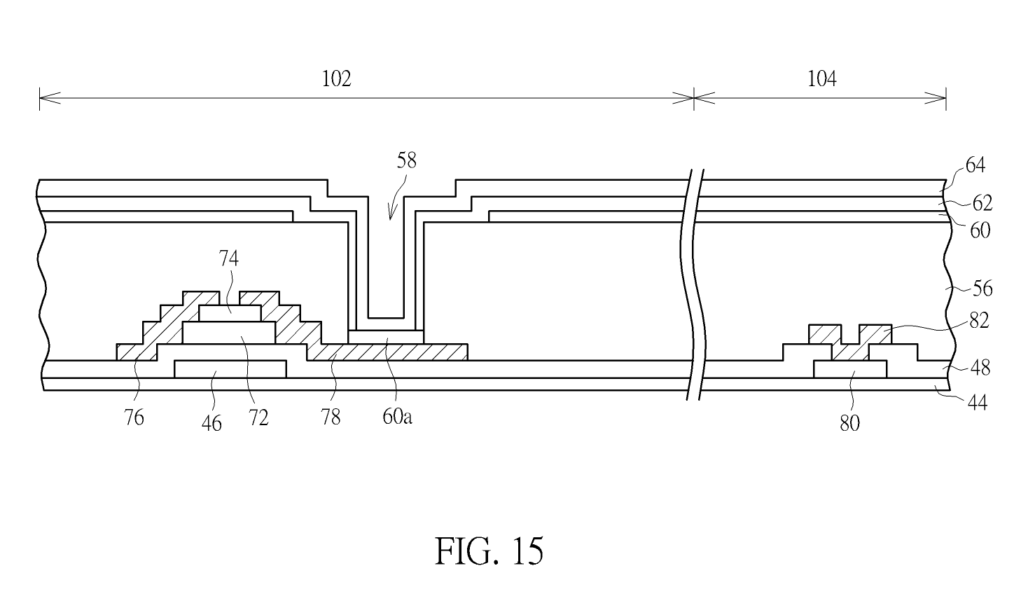

A thin film transistor array substrate in accordance with the sixth preferred embodiment and the fabrication the same is illustrated in FIG. 2, FIG. 14 and FIG. 15. FIG. 2 provides the layout of elements shown in the cross sectional views of FIG. 14 and FIG. 15. The difference between the present embodiment and the first preferred embodiment is characterized in forming the direct contact structure 34 within the fanout region 104 at the same time. Since the gate insulation layer 48 of the present embodiment need to be patterned to form the opening of the direct contact structure 34, an additional photolithography process is required, in comparison with the third preferred embodiment. As shown in FIG. 14, a first conductive layer is fabricated on the transparent substrate 44 through a first photolithography process, and the first conductive layer may comprise a scan line (do not shown in the drawing) within the display region 102, a gate electrode 46, and one or more than one of first contact layer 80, within the fanout region 104. Next, the gate insulation layer 48 is fabricated, wherein the gate insulation layer 48 covers the gate electrode 46, as well as the first contact layer 80. The contact hole is then fabricated on a portion of the gate insulation layer 48 being above each of the first contact layer 80, so as to expose the first contact layer 80 therebelow. As following, an oxide semiconductor layer 72 is fabricated on the gate insulation layer 48 through a third photolithography process, an etching stop layer 74 is fabricated on the oxide semiconductor layer 72 through a fourth photolithography process, and a second conductive layer is fabricated through a fifth photolithography process. The second conductive layer comprises a plurality of pairs of the source electrode 76 and the drain electrode 78, the data line disposed on other portions of the transparent substrate 44, and the second contact layer 82 disposed on the first contact layer 80 and filled in the contact hole. Thus, the thin film transistor of the present embodiment is consisted of the source electrode 76 the drain electrode 78, the oxide semiconductor layer 72, and the gate electrode 46, wherein the first contact layer 80 direct contacts to the second contact layer 82 through the contact hole, so as to form the direct contact structure 34.

Then, as shown in FIG. 15, similar to the third preferred embodiment, the first insulation layer 56 is formed to cover the display region 102 and the fanout region 104, as following, the contact hole 58 is fabricated through a sixth photolithography process; the common electrode 60 is fabricated through a seventh photolithography process; the second insulation layer 62 is fabricated through an eighth photolithography process; and the pixel electrode 64 is fabricated through a ninth photolithography process.

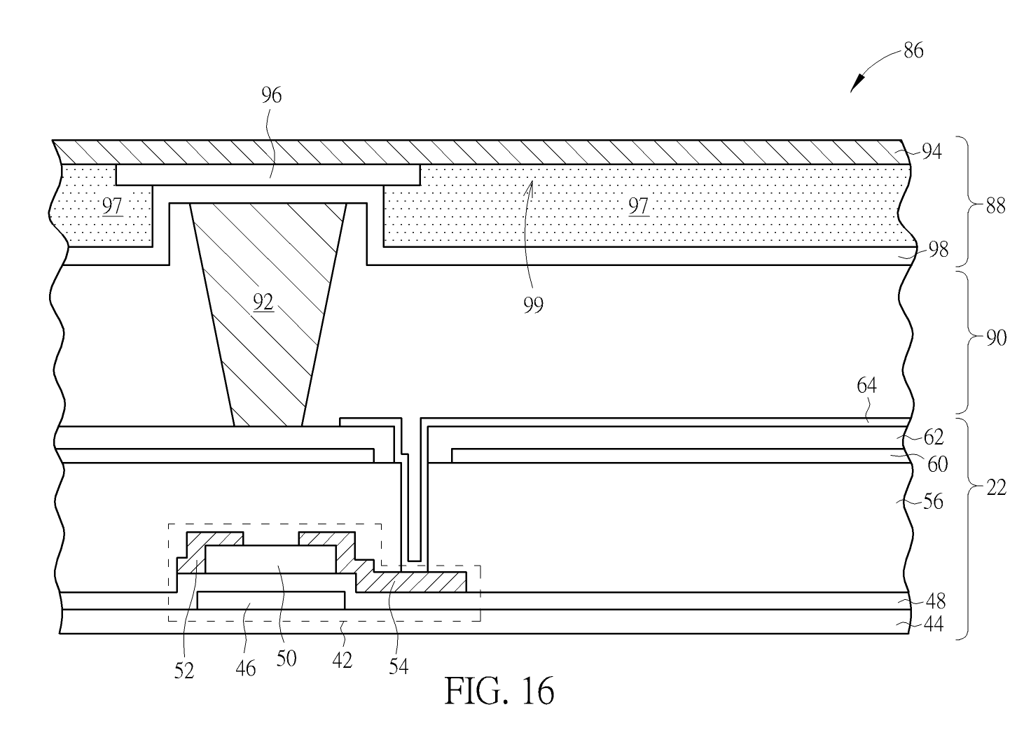

The thin film transistor array substrate of the present invention can be applied to liquid crystal display panels. Referring to FIG. 16, a liquid crystal display panel 86 comprises the thin film transistor array substrate 22, a color filter substrate 88, a liquid crystal layer 90 and a spacer 92. The color filter substrate 88 is disposed corresponding to the thin film transistor array substrate 22, and the liquid crystal layer 90 is disposed between the color filter substrate 88 and the thin film transistor array substrate 22. Also, the spacer 92 is disposed between the color filter substrate 88 and the thin film transistor array substrate 22, for sustaining the space between the color filter substrate 88 and the thin film transistor array substrate 22. The color filter substrate 88 comprises a substrate 94, a black matrix layer 96, a color filter layer 97 and another common electrode 98. The black matrix layer 96 is disposed on the substrate 94, and which comprises a plurality of openings 99 corresponding to the pixel regions 106 respectively and exposing a portion of the substrate 94. The color filter layer 97 covers the portion of the substrate 94 exposed from each of the openings 99, and the color filter layer 97 may comprise a plurality of color filter films including red color filter film, green color filter film and blue color filter film. The common electrode 98 covers on the color filter layer 97 and the black matrix layer 96, for receiving common signals. In other embodiments of the present invention, the color filter substrate may comprise two common electrodes for receiving different voltage signals, or may not comprise any common electrode. In other embodiments, each of the pixel electrodes may comprise particular patterned electrodes. Furthermore, invariant embodiment of the present invention, the thin film transistor array substrate can also be applied to other active matrix display panels, such as organic electroluminescent display panels.

In the present invention, the thin film transistor array substrate can achieve an increased aperture ratio of the pixel structure by fabricating an insulation layer (also known as a shielding layer, or a coating layer in the present invention) through the coating process, with the insulation layer being relative thick and not leading to any reduction of the a-IGZO oxide semiconductor layer. In additional, with such arrangement, the present invention can also keep unnecessary capacitive coupling from the a-IGZO TFT. Precisely speaking, the common electrode can be disposed between the pixel electrode and anyone of the thin film transistor, the scan line and the data line in the preset invention, for shielding the capacitive coupling between the pixel electrode and anyone of the thin film transistor, the data line and the scan line. Therefore, the gaps between the pixel electrode and at least one of thin film transistor, the data line and the scan line in a direction parallel to the first substrate can be effectively reduced to increase the aperture ratio of the pixel structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A thin film transistor array substrate, comprising:
a transparent substrate;
a plurality of thin film transistors, disposed on the transparent substrate, each of the thin film transistors comprising:
a gate electrode, disposed on the transparent substrate,
a gate insulation layer, disposed on the gate electrode and covering the transparent substrate,
an amorphous-oxide semiconductor layer, disposed on the gate insulation layer, and
a pair of a source electrode and a drain electrode, disposed on two sides of the amorphous-oxide semiconductor layer respectively, a portion of the source electrode and a portion of the drain electrode overlapping the amorphous-oxide semiconductor layer;
a first insulation layer, disposed on the thin film transistors and the transparent substrate;
a plurality of contact holes, each of the contact holes penetrating through the first insulation layer and exposing one of the pair of the source electrode and the drain electrode;
a common electrode, disposed on the first insulation layer, and the contact holes being exposed from the common electrode;
a second insulation layer, covering the common electrode; and
a plurality of pixel electrodes, each of the pixel electrodes disposed on the second insulation layer and filling in each of the contact holes respectively, thereby contacting the one of the pair of the source electrode and the drain electrode exposed by each of the contact holes.

2. The thin film transistor array substrate according to claim 1, wherein the amorphous-oxide semiconductor layer comprises an amorphous-oxide semiconductor material having indium oxide, gallium oxide and zinc oxide.

3. The thin film transistor array substrate according to claim 1, wherein the amorphous-oxide semiconductor layer is disposed between the first insulation layer and the pair of the source electrode and the drain electrode and contacts the gate insulation layer through a gap between the source electrode and the drain electrode.

4. The thin film transistor array substrate according to claim 1, wherein the amorphous-oxide semiconductor layer is disposed between the gate insulation layer and the source electrode and the drain electrode.

5. The thin film transistor array substrate according to claim 1, wherein the amorphous-oxide semiconductor layer is disposed between the gate insulation layer and the pair of the source electrode and the drain electrode and each of the thin film transistors further comprises:
an etching stop layer, disposed on the amorphous-oxide semiconductor layer, between the source electrode and the drain electrode.

6. The thin film transistor array substrate of claim 1, wherein a thickness of the first insulation layer is greater than a thickness of the second insulation layer.

7. A thin film transistor array substrate, comprising:
a transparent substrate, including a display region and a fanout region;
a plurality of thin film transistors, disposed on the transparent substrate within the display region, each of the thin film transistors comprising:
a gate electrode, disposed on the transparent substrate,
a gate insulation layer, disposed on the gate electrode and covering the transparent substrate,
an amorphous-oxide semiconductor layer, disposed on the gate insulation layer on the gate electrode, and
a pair of a source electrode and a drain electrode, disposed on two sides of the amorphous-oxide semiconductor layer respectively, a portion of the source electrode and a portion of the drain electrode overlapping the amorphous-oxide semiconductor layer respectively;
a plurality of direct contact structures, each of the direct contact structures being disposed on the transparent substrate within the fanout region, and each of the direct contact structures comprising:
a first contact layer, disposed on the transparent substrate and covered with the gate insulation layer,
a first contact hole, penetrating through the gate insulation layer and exposing the first contact layer, and
a second contact layer, disposed on the gate insulation layer and filling in the first contact hole, thereby contacting to the first contact layer;
a first insulation layer, disposed on the thin film transistors, the transparent substrate and the direct contact structures;
a plurality of second contact holes, each of the second contact holes penetrating through the first insulation layer and exposing one of the source electrode and the drain electrode;
a common electrode, disposed on the first insulation layer, the second contact holes being exposed from the common electrode;
a second insulation layer, covering the common electrode; and
a plurality of pixel electrodes, each of the pixel electrodes disposed on the second insulation layer and filling in the second contact holes, thereby contacting to one of the source electrode and the drain electrode corresponding to each of the pixel electrodes.

8. The thin film transistor array substrate of claim 7, wherein the amorphous-oxide semiconductor layer comprises an amorphous-oxide semiconductor material having indium oxide, gallium oxide and zinc oxide.

9. The thin film transistor array substrate of claim 7, wherein a material of the first contact layer is the same as a material of the gate electrode.

10. The thin film transistor array substrate of claim 7, wherein a material of the second contact layer is the same as a material of the pair of the source electrode and the drain electrode.

11. A thin film transistor array substrate, comprising:
a transparent substrate;
a plurality of thin film transistors, disposed on the transparent substrate, each of the thin film transistors comprising:
a gate electrode, disposed on the transparent substrate,
a gate insulation layer, disposed on the gate electrode and covering the transparent substrate,
an amorphous-oxide semiconductor layer, disposed on the gate insulation layer on the gate electrode, and
a pair of a source electrode and a drain electrode, disposed on two sides of the amorphous-oxide semiconductor layer respectively, a portion of the source electrode and a portion of the drain electrode overlapping the amorphous-oxide semiconductor layer, and the pair of the source electrode and the drain electrode comprising a first end and a second end;
a plurality of scan lines, electrically connected to the gate electrodes of thin film transistors respectively;
a plurality of data lines, electrically connected to the first ends of the source electrodes and the drain electrodes respectively;
a first insulation layer, disposed on the thin film transistors, the scan lines, the data lines and the transparent substrate;
a plurality of contact holes, each of the contact holes penetrating through the first insulation layer and exposing the second end of the source electrode and the drain electrode corresponding to each of the contact holes respectively;
a common electrode, disposed on the first insulation layer, the contact holes being exposed from the common electrode;
a second insulation layer, covering the common electrode; and
a plurality of pixel electrodes, each of the pixel electrodes disposed on the second insulation layer and filling in one of the contact holes, thereby contacting to the second end of the source electrode and the drain electrode corresponding to each of the pixel electrodes.

12. The thin film transistor array substrate of claim 11, wherein the amorphous-oxide semiconductor layer comprises an amorphous-oxide semiconductor material having indium oxide, gallium oxide and zinc oxide.

13. The thin film transistor array substrate of claim 11, wherein each of the pixel electrodes overlaps a portion of at least one of the scan lines or the data lines, and the first insulation layer and the common electrode are sandwiched between each of the pixel electrodes and the portion of at least one of the scan lines or the data lines.
